(19) United States
(12) Patent Application Publication
(10) Pub. No.: US 2026/0135524 A1
(43) Pub. Date: May 14, 2026

(54) BALANCE-TYPE AMPLIFIER

(71) Applicant: Mitsubishi Electric Corporation, Tokyo (JP)

(72) Inventors: Keigo NAKATANI, Tokyo (JP); Kento SAIKI, Tokyo (JP); Jun KAMIOKA, Tokyo (JP)

(73) Assignee: Mitsubishi Electric Corporation, Tokyo (JP)

(21) Appl. No.: 19/397,116

(22) Filed: Nov. 21, 2025

Related U.S. Application Data
(63) Continuation of application No. PCT/JP2023/022172, filed on Jun. 15, 2023.

(51) Int. Cl. H03F 1/56; H01P 5/16; H03F 3/60

(52) U.S. Cl. CPC H03F 1/56; H01P 5/16; H03F 3/602

(57) ABSTRACT

A balance-type amplifier includes: a signal divider circuit to divide an amplification target signal into first and second signals and output them; a first amplifier to amplify the first signal; a second amplifier to amplify the second signal; and a synthesis circuit to synthesize the amplified first signal and the amplified second signal. The first amplifier includes a first matching circuit to match an output impedance of the first amplifier with a first impedance different from an impedance of a load connected with an output side of the synthesis circuit. The second amplifier of the balance-type amplifier includes a second matching circuit to match an output impedance of the second amplifier with a second impedance different from the impedance of the load. One of the first and second impedances is higher than the impedance of the load, and another of them is lower than the impedance of the load.

### CROSS REFERENCE TO RELATED APPLICATION

This application is a Continuation of PCT International Application No. PCT/JP2023/022172, filed on Jun. 15, 2023, which is hereby expressly incorporated by reference into the present application.

### TECHNICAL FIELD

The present disclosure relates to a balance-type amplifier.

### BACKGROUND ART

As for amplifiers for wireless communication, there is, for example, a balance-type amplifier including two amplifiers.

As for such a balance-type amplifier, for example, Patent Literature 1 discloses a high frequency circuit that includes a 90° hybrid circuit, a first amplifier, a second amplifier, a 90° phase shifter, and an isolator module.

The 90° hybrid circuit divides a high frequency signal into two signals, outputs a first high frequency signal as one of the two divided signals to the first amplifier, and outputs a second high frequency signal as the other signal of the two divided signals to the second amplifier. The first amplifier amplifies the first high frequency signal, and outputs the amplified first high frequency signal to the 90° phase shifter. The 90° phase shifter delays the phase of the amplified first high frequency signal by 90°, and outputs the first high frequency signal subjected to phase shift to the isolator module. The second amplifier amplifies the second high frequency signal, and outputs the amplified second high frequency signal to the isolator module. The isolator module synthesizes the first high frequency signal output from the 90° phase shifter and the second high frequency signal output from the second amplifier, and outputs a synthesis signal of the first high frequency signal and the second high frequency signal to a load.

### CITATION LIST

### Patent Literature

Patent Literature 1: JP 2013-236144 A

### SUMMARY OF INVENTION

### Technical Problem

The high frequency circuit disclosed in Patent Literature 1 has a problem that output electrical power and efficiency decrease due to change of an impedance of the load connected with an output side of the isolator module.

The present disclosure has been made to solve the above problem, and an object of the present disclosure is to obtain a balance-type amplifier that can suppress output electrical power and efficiency from decreasing even when an impedance of a load changes.

### Solution to Problem

A balance-type amplifier according to the present disclosure includes: a signal divider circuit to divide an amplification target signal into two divided signals including a first signal and a second signal, output the first signal and the second signal; a first amplifier to amplify the first signal output from the signal divider circuit; a second amplifier to amplify the second signal output from the signal divider circuit; and a synthesis circuit to perform synthesization of the first signal amplified by the first amplifier and the second signal amplified by the second amplifier. An output phase circuit having an electrical length of 90 degrees and provided between the first amplifier and the synthesis circuit. An input phase circuit provided between the signal divider circuit and the second amplifier, the input phase circuit performing a phase shift of a phase of the second signal output from the signal divider circuit in such a way that a phase of the first signal amplified by the first amplifier and the phase of the second signal amplified by the second amplifier are in-phase at a point of the synthesization in the synthesis circuit of the first signal amplified by the first amplifier and the second signal amplified by the second amplifier. The first amplifier of the balance-type amplifier includes a first matching circuit to match an output impedance of the first amplifier with a first impedance different from an impedance of a load connected with an output side of the synthesis circuit. The second amplifier of the balance-type amplifier includes a second matching circuit to match an output impedance of the second amplifier with a second impedance different from the impedance of the load. One of the first impedance and the second impedance is higher than the impedance of the load, and the other of the first impedance and the second impedance is lower than the impedance of the load. The synthesis circuit includes a 90-degree hybrid circuit including: a first terminal to which the first signal amplified by the first amplifier is given, a second terminal to which the second signal amplified by the second amplifier is given; and a third terminal to output a synthesis signal of the first signal amplified by the first amplifier and the second signal amplified by the second amplifier.

### Advantageous Effects of Invention

According to the present disclosure, it is possible to suppress output electrical power and efficiency from decreasing even when an impedance of a load changes.

### BRIEF DESCRIPTION OF DRAWINGS

FIG. 1 is a configuration diagram illustrating a balance-type amplifier according to Embodiment 1.

FIG. 2A is a configuration diagram illustrating the interior of a first amplifier 3, and FIG. 2B is a configuration diagram illustrating the interior of a second amplifier 6.

FIG. 3A is a smith chart illustrating an output impedance of the first amplifier 3 and an output impedance of the second amplifier 6 after a load impedance Z₀ changes from 50Ω to 25Ω, and FIG. 3B is a smith chart illustrating an output impedance of the first amplifier 3 and an output impedance of the second amplifier 6 after the load impedance Z₀ changes from 50Ω to 75Ω.

FIG. 4A is a smith chart illustrating an output impedance of a first amplifier and an output impedance of a second amplifier in a general balance-type amplifier after the load impedance Z₀ changes from 50Ω to 25Ω, and FIG. 4B is a smith chart illustrating an output impedance of the first amplifier and an output impedance of the second amplifier in the general balance-type amplifier after the load impedance Z₀ changes from 50Ω to 75Ω.

FIG. 5 is a smith chart illustrating load impedance dependency of efficiency in the balance-type amplifier illustrated in FIG. 1 and the general balance-type amplifier as contours.

FIG. 6 is a smith chart illustrating load impedance dependency of output electrical power in the balance-type amplifier illustrated in FIG. 1 and the general balance-type amplifier as contours.

FIG. 7 is a configuration diagram illustrating a balance-type amplifier according to Embodiment 2.

FIG. 8 is a configuration diagram illustrating a balance-type amplifier according to Embodiment 3.

FIG. 9 is a configuration diagram illustrating a balance-type amplifier according to Embodiment 4.

FIG. 10 is a configuration diagram illustrating a balance-type amplifier according to Embodiment 5.

FIG. 11 is a configuration diagram illustrating a balance-type amplifier according to Embodiment 6.

FIG. 12 is a configuration diagram illustrating a balance-type amplifier according to Embodiment 7.

### DESCRIPTION OF EMBODIMENTS

Hereinafter, a mode for carrying out the present disclosure will be described with reference to the accompanying drawings to describe the present disclosure in more detail.

### Embodiment 1

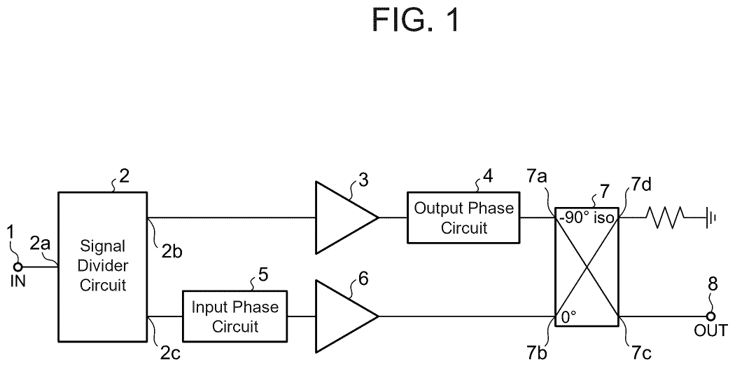

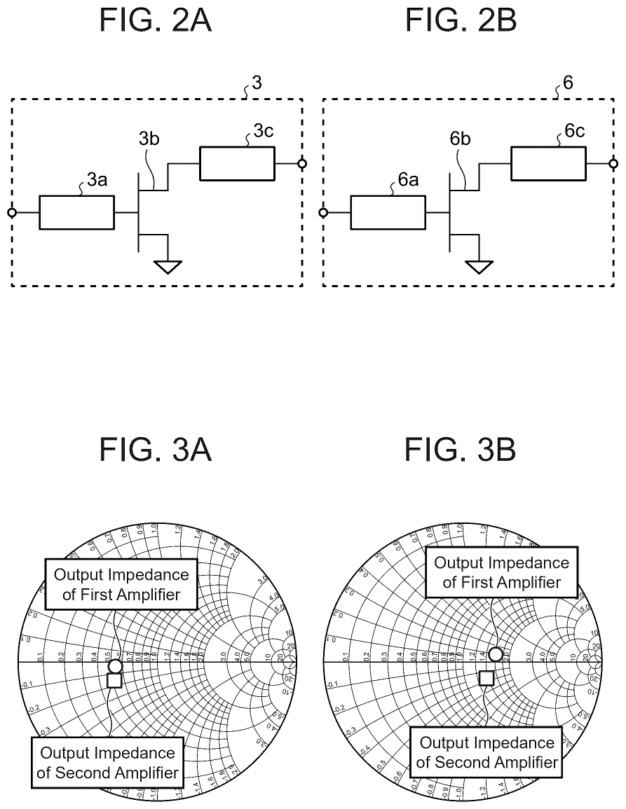

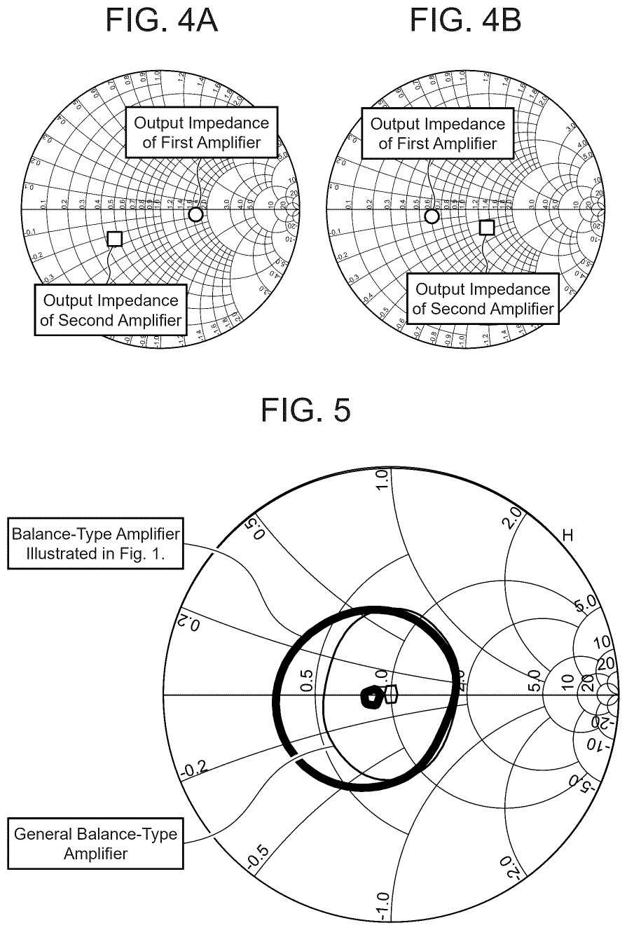

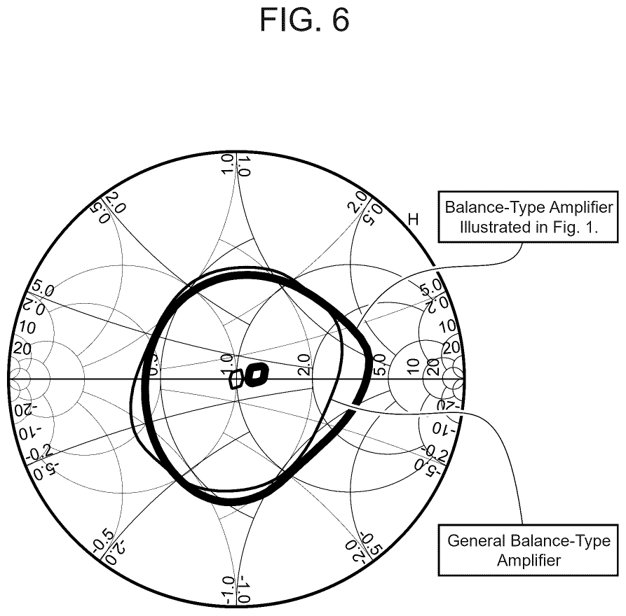

FIG. 1 is a configuration diagram illustrating a balance-type amplifier according to Embodiment 1.

The balance-type amplifier illustrated in FIG. 1 includes a signal input terminal 1, a signal divider circuit 2, a first amplifier 3, an output phase circuit 4, an input phase circuit 5, a second amplifier 6, a synthesis circuit 7, and a signal output terminal 8.

A high frequency signal is given as an amplification target signal to the signal input terminal 1.

The signal divider circuit 2 includes a first terminal 2a, a second terminal 2b, and a third terminal 2c.

The high frequency signal given to the signal input terminal 1 is given to the first terminal 2a of the signal divider circuit 2.

The signal divider circuit 2 divides the high frequency signal into two signals.

The signal divider circuit 2 outputs a first signal as one of the two divided signals from the second terminal 2b to the first amplifier 3, and outputs a second signal as the other signal of the two divided signals from the third terminal 2c to the input phase circuit 5.

The first amplifier 3 is implemented as, for example, a semi-discrete amplifier enclosed in a high frequency package or a Monolithic Microwave Integrated Circuit (MMIC) type amplifier formed on a semiconductor substrate.

The first amplifier 3 includes a first matching circuit to match an output impedance of the first amplifier 3 with a first impedance different from an impedance of a load (hereinafter, referred to as a “load impedance Z₀”) connected with an output side of the synthesis circuit 7.

In the balance-type amplifier illustrated in FIG. 1, the first impedance is an impedance higher than the load impedance Z₀.

The first amplifier 3 amplifies the first signal output from the second terminal 2b of the signal divider circuit 2.

The first amplifier 3 outputs the amplified first signal to the output phase circuit 4.

One end of the output phase circuit 4 is connected with an output side of the first amplifier 3.

The other end of the output phase circuit 4 is connected with a first terminal 7a that is a terminal on an input side of the synthesis circuit 7.

The output phase circuit 4 is a circuit that has an electrical length of 90 degrees. When the first signal amplified by the first amplifier 3 passes the output phase circuit 4, the phase of the amplified first signal is delayed by 90 degrees.

The first signal subjected to phase shift by the output phase circuit 4 is given to the first terminal 7a of the synthesis circuit 7.

One end of the input phase circuit 5 is connected with the third terminal 2c of the signal divider circuit 2.

The other end of the input phase circuit 5 is connected with an input side of the second amplifier 6.

The input phase circuit 5 changes the phase of the second signal output from the third terminal 2c of the signal divider circuit 2 in such a way that the phase of the amplified first signal and the phase of the amplified second signal are in-phase at a synthesis point of the first signal amplified by the first amplifier 3 and the second signal amplified by the second amplifier 6 in the synthesis circuit 7. A third terminal 7c of the synthesis circuit 7 corresponds to the synthesis point of the synthesis circuit 7.

The second amplifier 6 is implemented as, for example, a semi-discrete amplifier enclosed in a high frequency package or an MMIC type amplifier formed on a semiconductor substrate.

The second amplifier 6 includes a second matching circuit that matches an output impedance of the second amplifier 6 with a second impedance different from the load impedance Z₀.

In the balance-type amplifier illustrated in FIG. 1, the second impedance is an impedance lower than the load impedance Z₀.

The second amplifier 6 amplifies the second signal output from the input phase circuit 5.

The second amplifier 6 outputs the amplified second signal to a second terminal 7b that is a terminal on the input side of the synthesis circuit 7.

The synthesis circuit 7 is implemented as, for example, a 90-degree hybrid circuit.

The synthesis circuit 7 includes the first terminal 7a, the second terminal 7b, the third terminal 7c, and a fourth terminal 7d.

Each of the first terminal 7a and the second terminal 7b is an input terminal, the third terminal 7c is an output terminal, and the fourth terminal 7d is an isolation terminal that is grounded via a resistance.

The first signal output from the output phase circuit 4 is given to the first terminal 7a of the synthesis circuit 7.

The second signal amplified by the second amplifier 6 is given to the second terminal 7b of the synthesis circuit 7.

The synthesis circuit 7 synthesizes the first signal and the second signal.

The synthesis circuit 7 outputs the synthesis signal of the first signal and the second signal from the third terminal 7c to the signal output terminal 8.

The signal output terminal 8 is connected with an unillustrated load.

The load impedance Z₀ may change from, for example, 50Ω.

FIG. 2A is a configuration diagram illustrating the interior of the first amplifier 3.

The first amplifier 3 illustrated in FIG. 2A includes an input matching circuit 3a, a first amplification element 3b, and an output matching circuit 3c.

One end of the input matching circuit 3a is connected with the second terminal 2b of the signal divider circuit 2.

The other end of the input matching circuit 3a is connected with an input terminal of the first amplification element 3b.

The input matching circuit 3a matches an input impedance of the first amplification element 3b with an impedance of an input side of the signal input terminal 1.

The input terminal of the first amplification element 3b is connected with the other end of the input matching circuit 3a.

An output terminal of the first amplification element 3b is connected with one end of the output matching circuit 3c.

The first amplification element 3b is implemented as, for example, a silicon semiconductor transistor, a Lateral Double Diffused MOS (LDMOS) semiconductor transistor, a gallium arsenide semiconductor transistor, or a gallium nitride semiconductor transistor.

The first amplification element 3b amplifies the first signal having passed the input matching circuit 3a.

The first amplification element 3b outputs the amplified first signal to the output matching circuit 3c.

The one end of the output matching circuit 3c is connected with the output terminal of the first amplification element 3b.

The other end of the output matching circuit 3c is connected with one end of the output phase circuit 4.

The output matching circuit 3c functions as a first matching circuit to match an output impedance of the first amplification element 3b with the first impedance higher than the load impedance Z₀.

Since the load impedance Z₀ is generally 50Ω, the output matching circuit 3c matches the output impedance of the first amplification element 3b with the first impedance higher than 50Ω.

FIG. 2B is a configuration diagram illustrating the interior of the second amplifier 6.

The second amplifier 6 illustrated in FIG. 2B includes an input matching circuit 6a, a second amplification element 6b, and an output matching circuit 6c.

One end of the input matching circuit 6a is connected with the other end of the input phase circuit 5.

The other end of the input matching circuit 6a is connected with an input terminal of the second amplification element 6b.

The input matching circuit 6a matches an input impedance of the second amplification element 6b with the impedance of the input side of the signal input terminal 1.

The input terminal of the second amplification element 6b is connected with the other end of the input matching circuit 6a.

An output terminal of the second amplification element 6b is connected with one end of the output matching circuit 6c.

The second amplification element 6b is implemented as, for example, a silicon semiconductor transistor, an LDMOS semiconductor transistor, a gallium arsenide semiconductor transistor, or a gallium nitride semiconductor transistor.

The second amplification element 6b amplifies the second signal having passed the input matching circuit 6a.

The second amplification element 6b outputs the amplified second signal to the output matching circuit 6c.

The one end of the output matching circuit 6c is connected with the output terminal of the second amplification element 6b.

The other end of the output matching circuit 6c is connected with the second terminal 7b of the synthesis circuit 7.

The output matching circuit 6c functions as a second matching circuit to match an output impedance of the second amplification element 6b with the second impedance lower than the load impedance Z₀.

Since the load impedance Z₀ is generally 50Ω, the output matching circuit 6c matches the output impedance of the second amplification element 6b with the second impedance lower than 50Ω.

Next, an operation of the balance-type amplifier illustrated in FIG. 1 will be described.

The signal divider circuit 2 divides the high frequency signal given to the signal input terminal 1 into two signals.

The signal divider circuit 2 outputs the first signal as one of the two divided signals from the second terminal 2b to the first amplifier 3.

The signal divider circuit 2 outputs the second signal as the other signal of the two divided signals from the third terminal 2c to the input phase circuit 5.

The first amplification element 3b of the first amplifier 3 amplifies the first signal output from the second terminal 2b of the signal divider circuit 2.

At this time, the output matching circuit 3c of the first amplifier 3 matches the output impedance of the first amplification element 3b with the first impedance higher than the load impedance Z₀. If the load impedance Z₀ is 50Ω, the output matching circuit 3c matches the output impedance of the first amplification element 3b with the first impedance higher than 50Ω.

The first amplifier 3 outputs the amplified first signal to the output phase circuit 4.

The output phase circuit 4 delays the phase of the first signal amplified by the first amplifier 3 by 90 degrees.

The first signal subjected to phase shift by the output phase circuit 4 is given to the first terminal 7a of the synthesis circuit 7.

The phase of the first signal given to the first terminal 7a of the synthesis circuit 7 is further delayed by 90 degrees by the synthesis circuit 7. Thus, the phase of the first signal is delayed by 180 degrees in total, and the first signal delayed by 180 degrees is given to the third terminal 7c of the synthesis circuit 7.

The input phase circuit 5 changes the phase of the second signal output from the third terminal 2c of the signal divider circuit 2 in such a way that the phase of the first signal amplified by the first amplifier 3 and the phase of the second signal amplified by the second amplifier 6 are in-phase at the third terminal 7c of the synthesis circuit 7.

More specifically, if the phase of the first signal amplified by the third terminal 7c is θ₁, and, in a case where the input phase circuit 5 is not present, the phase of the second signal amplified by the third terminal 7c is θ₂ and the phase delayed by the input phase circuit 5 is θ₃, the phase θ₃ delayed by the input phase circuit 5 is expressed by, for example, the following equation (1) or equation (2).

$${θ}_{3} = 360 - \vert {θ}_{1} + {θ}_{2} \vert \qquad ( 1 )$$

$${θ}_{3} = 0 - \vert {θ}_{1} + {θ}_{2} \vert \qquad ( 2 )$$

If, for example, the phase θ₁ of the first signal is −180 degrees and the phase θ₂ of the second signal is 0 degree, the input phase circuit 5 has such an electrical length that the phase of −180 degrees changes or such an electrical length that the phase of +180 degrees changes, so that the phase of the first signal and the phase of the second signal are in-phase at the third terminal 7c.

Here, the phase θ₃ delayed by the input phase circuit 5 is expressed by the equation (1) or the equation (2). The phase of the first signal and the phase of the second signal only need to be in-phase at the third terminal 7c of the third terminal 7c, and the phase θ₃ is not limited to a phase expressed by the equation (1) or the equation (2).

The second amplification element 6b of the second amplifier 6 amplifies the second signal output from the input phase circuit 5.

At this time, the output matching circuit 6c of the second amplifier 6 matches the output impedance of the second amplification element 6b with the second impedance lower than the load impedance Z₀. If the load impedance Z₀ is 50Ω, the output matching circuit 6c matches the output impedance of the second amplification element 6b with the second impedance lower than 50Ω.

The second amplifier 6 outputs the amplified second signal to the second terminal 7b of the synthesis circuit 7.

The first signal output from the output phase circuit 4 is given to the first terminal 7a of the synthesis circuit 7.

The second signal amplified by the second amplifier 6 is given to the second terminal 7b of the synthesis circuit 7.

The synthesis circuit 7 synthesizes the first signal and the second signal in-phase after delaying by 90 degrees the phase of the first signal given to the first terminal 7a.

The synthesis circuit 7 outputs the synthesis signal of the first signal and the second signal from the third terminal 7c to the unillustrated load via the signal output terminal 8.

Next, an effect of the balance-type amplifier illustrated in FIG. 1 will be described.

FIG. 3A is a smith chart illustrating the output impedance of the first amplifier 3 and the output impedance of the second amplifier 6 after the load impedance Z₀ changes from 50Ω to 25Ω. In FIG. 3A, a mark ∘ represents the output impedance of the first amplifier 3, and a mark represents the output impedance of the second amplifier 6.

FIG. 4A is a smith chart illustrating the output impedance of the first amplifier and the output impedance of the second amplifier in a general balance-type amplifier after the load impedance Z₀ changes from 50Ω to 25Ω. The general balance-type amplifier corresponds to a high frequency circuit disclosed in Patent Literature 1. The output impedance of the first amplifier in the general balance-type amplifier is matched with the load impedance Z₀, and the output impedance of the second amplifier in the general balance-type amplifier is matched with the load impedance Z₀. In FIG. 4A, a mark ∘ represents the output impedance of the first amplifier, and a black mark represents the output impedance of the second amplifier.

When the load impedance Z₀ changes from 50Ω to 25Ω in the general balance-type amplifier, as illustrated in FIG. 4A, the output impedance of the first amplifier and the output impedance of the second amplifier change in opposite directions. That is, the output impedance of the first amplifier changes in the same direction as that of the load impedance Z₀, and the output impedance of the second amplifier changes in a direction opposite to that of the load impedance Z₀. As a result, when the load impedance Z₀ changes from 50Ω to 25Ω, a difference between the output impedance of the first amplifier and the output impedance of the second amplifier becomes greater.

By contrast with this, when the load impedance Z₀ changes from 50Ω to 25Ω in the balance-type amplifier illustrated in FIG. 1, as illustrated in FIG. 3A, the output impedance of the first amplifier 3 and the output impedance of the second amplifier 6 change in the same direction. That is, the output impedance of the first amplifier 3 and the output impedance of the second amplifier 6 change in the same direction as that of the load impedance Z₀. As a result, even when the load impedance Z₀ changes from 50Ω to 25Ω, the difference between the output impedance of the first amplifier 3 and the output impedance of the second amplifier 6 does not become greater than the difference between the output impedance of the first amplifier and the output impedance of the second amplifier in the general balance-type amplifier.

Here, a difference between the output impedance of the first amplifier 3 and the output impedance of the second amplifier 6 will be more specifically described. In this regard, for simplicity of description, the difference will be described by ignoring the functions in the output matching circuit 3c of the first amplifier 3 and the output matching circuit 6c of the second amplifier 6.

A case is assumed where change of a reflection coefficient Γ has occurred as change of the output impedance in each of the signal output terminal of the general balance-type amplifier and the signal output terminal 8 of the balance-type amplifier illustrated in FIG. 1.

In a case where a reflection coefficient of the first amplifier is Γ₁, a reflection phase of the first amplifier θ₁, a reflection coefficient of the second amplifier is Γ₂, and a reflection phase of the second amplifier is θ₂ in the general balance-type amplifier, since the balance-type amplifier includes a 90-degree hybrid circuit as a synthesis circuit, the following equation (3) and equation (4) hold.

$${Γ}_{1} = {Γ}_{2} \qquad ( 3 )$$

$${θ}_{1} = {θ}_{2} + 180 \qquad ( 4 )$$

Each of the equation (3) and the equation (4) means that, when the output impedance of the signal output terminal changes, the reflection coefficient Γ₁ of the first amplifier and the reflection coefficient Γ₂ of the second amplifier move out of phase with the same amplitude amount. Hence, when the load impedance Z₀ changes, the difference between the output impedance of the first amplifier and the output impedance of the second amplifier becomes greater. When the difference becomes greater, and when the synthesis circuit synthesizes two signals, loss occurs, and, as a result, output electrical power and efficiency decrease.

By contrast with this, since the balance-type amplifier illustrated in FIG. 1 includes the output phase circuit 4 and the input phase circuit 5, the following equation (5) and equation (6) hold.

$${Γ}_{1} = {Γ}_{2} \qquad ( 5 )$$

$${θ}_{1} = {θ}_{2}$$

Each of the equation (5) and the equation (6) means that, when the output impedance of the signal output terminal 8 changes, the reflection coefficient Γ₁ of the first amplifier 3 and the reflection coefficient Γ₂ of the second amplifier 6 move in-phase with the same amplitude amount. Hence, even when the load impedance Z₀ changes, the difference between the output impedance of the first amplifier 3 and the output impedance of the second amplifier 6 does not become greater. The difference does not become greater, so that loss caused when the synthesis circuit 7 synthesizes two signals is reduced, and, as a result, output electrical power and efficiency improve.

FIG. 3B is a smith chart illustrating the output impedance of the first amplifier 3 and the output impedance of the second amplifier 6 after the load impedance Z₀ changes from 50Ω to 75Ω. In FIG. 3B, a mark ∘ represents the output impedance of the first amplifier 3, and a mark represents the output impedance of the second amplifier 6.

FIG. 4B is a smith chart illustrating an output impedance of the first amplifier and an output impedance of the second amplifier in the general balance-type amplifier after the load impedance Z₀ changes from 50Ω to 75Ω. The output impedance of the first amplifier in the general balance-type amplifier is matched with the load impedance Z₀, and the output impedance of the second amplifier in the general balance-type amplifier is matched with the load impedance Z₀. In FIG. 4B, a mark ∘ represents the output impedance of the first amplifier, and a mark □ represents the output impedance of the second amplifier.

In the general balance-type amplifier, when the load impedance Z₀ changes from 50Ω to 75Ω, the output impedance of the first amplifier and the output impedance of the second amplifier change in opposite directions as illustrated in FIG. 4B. That is, the output impedance of the first amplifier changes in the same direction as that of the load impedance Z₀, and the output impedance of the second amplifier changes in a direction opposite to that of the load impedance Z₀. As a result, when the load impedance Z₀ changes from 50Ω to 75Ω, the difference between the output impedance of the first amplifier and the output impedance of the second amplifier becomes greater.

By contrast with this, in the balance-type amplifier illustrated in FIG. 1, when the load impedance Z₀ changes from 50Ω to 75Ω, the output impedance of the first amplifier 3 and the output impedance of the second amplifier 6 change in the same direction as illustrated in FIG. 3B. That is, the output impedance of the first amplifier 3 and the output impedance of the second amplifier 6 change in the same direction as that of the load impedance Z₀. As a result, even when the load impedance Z₀ changes from 50Ω to 75Ω, the difference between the output impedance of the first amplifier 3 and the output impedance of the second amplifier 6 does not become greater than the difference between the output impedance of the first amplifier and the output impedance of the second amplifier in the general balance-type amplifier.

FIG. 5 is a smith chart illustrating load impedance dependency of efficiency in the balance-type amplifier illustrated in FIG. 1 and the general balance-type amplifier as contours.

In FIG. 5, the contours of the efficiency are displayed as contours of 10 pt.

A contour range of the efficiency of 10 pt in the balance-type amplifier illustrated in FIG. 1 is wider than that of the general balance-type amplifier as illustrated in FIG. 5. Consequently, it is found that the balance-type amplifier illustrated in FIG. 1 can obtain high efficiency with the load impedance Z₀ different from 50Ω.

FIG. 6 is a smith chart illustrating load impedance dependency of output electrical power in the balance-type amplifier illustrated in FIG. 1 and the general balance-type amplifier as contours.

In FIG. 6, the contours of the output electrical power are displayed as contours of 2 dB.

A contour range of the output electrical power of 2 dB in the balance-type amplifier illustrated in FIG. 1 is wider than that of the general balance-type amplifier as illustrated in FIG. 6. Consequently, it is found that the balance-type amplifier illustrated in FIG. 1 can obtain high output electrical power with the load impedance Z₀ different from 50Ω.

In above Embodiment 1, the balance-type amplifier is configured to include the signal divider circuit 2 that divides an amplification target signal into two signals, outputs the first signal as one signal of the two divided signals, and outputs the second signal as the other signal of the two divided signals, the first amplifier 3 that amplifies the first signal output from the signal divider circuit 2, the second amplifier 6 that amplifies the second signal output from the signal divider circuit 2, and the synthesis circuit 7 that synthesizes the first signal amplified by the first amplifier 3 and the second signal amplified by the second amplifier 6. Furthermore, the first amplifier 3 of the balance-type amplifier includes the first matching circuit that matches the output impedance of the first amplifier 3 with the first impedance different from the impedance of the load connected with the output side of the synthesis circuit 7. The second amplifier 6 of the balance-type amplifier includes the second matching circuit that matches the output impedance of the second amplifier 6 with the second impedance different from the impedance of the load. One impedance of the first impedance and the second impedance is higher than the impedance of the load, and the other impedance of the first impedance and the second impedance is lower than the impedance of the load. Accordingly, the balance-type amplifier can suppress output electrical power and efficiency from decreasing even when the impedance of the load changes.

In the balance-type amplifier illustrated in FIG. 1, the output matching circuit 3c of the first amplifier 3 matches the output impedance of the first amplification element 3b with the impedance higher than the load impedance Z₀, and the output matching circuit 6c of the second amplifier 6 matches the output impedance of the second amplification element 6b with the impedance lower than the load impedance Z₀. However, this is merely an example, and the output matching circuit 3c of the first amplifier 3 matches the output impedance of the first amplification element 3b with the impedance lower than the load impedance Z₀, and the output matching circuit 6c of the second amplifier 6 matches the output impedance of the second amplification element 6b with the impedance higher than the load impedance Z₀. In this case, too, the balance-type amplifier can suppress output electrical power and efficiency from decreasing even when the impedance of the load changes.

### Embodiment 2

Embodiment 2 will describe a balance-type amplifier in which the output phase circuit 4 is provided between the second amplifier 6 and the synthesis circuit 7, and the input phase circuit 5 is provided between the signal divider circuit 2 and the first amplifier 3.

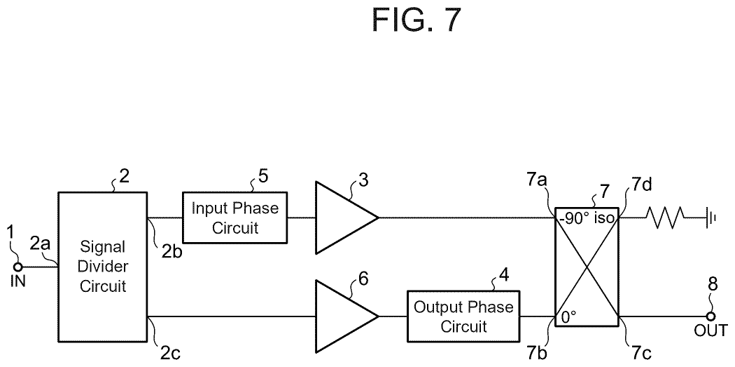

FIG. 7 is a configuration diagram illustrating the balance-type amplifier according to Embodiment 2. Note that, in FIG. 7, the same reference numerals as those in FIG. 1 indicate identical or corresponding parts, and therefore detailed description thereof will be omitted.

In the balance-type amplifier illustrated in FIG. 7, the output phase circuit 4 is provided between the second amplifier 6 and the synthesis circuit 7.

Furthermore, in the balance-type amplifier illustrated in FIG. 7, the input phase circuit 5 is provided between the signal divider circuit 2 and the first amplifier 3.

The input phase circuit 5 changes the phase of the first signal output from the second terminal 2b of the signal divider circuit 2 in such a way that the phase of the amplified first signal and the phase of the amplified second signal are in-phase at a synthesis point of the first signal amplified by the first amplifier 3 and the second signal amplified by the second amplifier 6 in the synthesis circuit 7. The third terminal 7c of the synthesis circuit 7 corresponds to the synthesis point of the synthesis circuit 7.

Also in the balance-type amplifier illustrated in FIG. 7, one of the first impedance and the second impedance is higher than the load impedance Z₀, and the other of the first impedance and the second impedance is lower than the load impedance Z₀ similarly to the balance-type amplifier illustrated in FIG. 1. Accordingly, the balance-type amplifier illustrated in FIG. 7 can suppress output electrical power and efficiency from decreasing even when the load impedance Z₀ changes.

### Embodiment 3

Embodiment 3 will describe a balance-type amplifier in which the signal divider circuit 2 includes a 90-degree hybrid circuit 9.

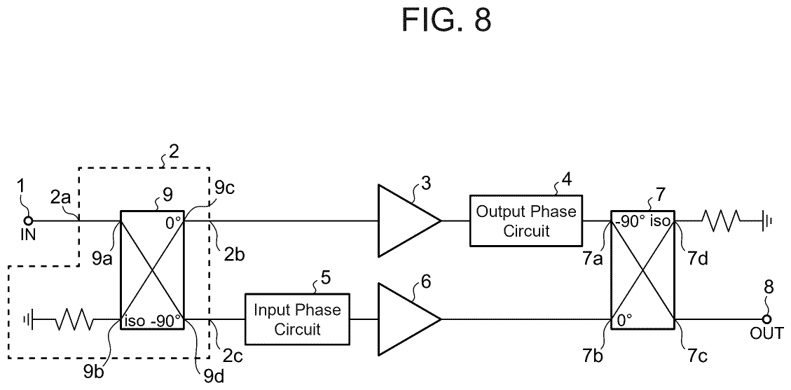

FIG. 8 is a configuration diagram illustrating the balance-type amplifier according to Embodiment 3. Note that, in FIG. 8, the same reference numerals as those in FIG. 1 indicate identical or corresponding parts, and therefore detailed description thereof will be omitted.

The 90-degree hybrid circuit 9 includes a first terminal 9a, a second terminal 9b, a third terminal 9c, and a fourth terminal 9d.

The first terminal 9a is an input terminal to which a high frequency signal that is an amplification target signal is given, and the second terminal 9b is an isolation terminal that is grounded via a resistance.

The third terminal 9c is an output terminal that outputs a first signal, and the fourth terminal 9d is an output terminal that outputs a second signal.

When the high frequency signal is given to the first terminal 9a, the 90-degree hybrid circuit 9 divides the high frequency signal into two signals.

The 90-degree hybrid circuit 9 outputs the first signal as one of the two divided signals from the third terminal 9c to the first amplifier 3, and outputs the second signal as the other signal of the two divided signals from the fourth terminal 9d to the input phase circuit 5.

In the balance-type amplifier illustrated in FIG. 8, the 90-degree hybrid circuit 9 is applied to the balance-type amplifier illustrated in FIG. 1. However, this is merely an example, and the 90-degree hybrid circuit 9 may be applied to the balance-type amplifier illustrated in FIG. 7.

Also in the balance-type amplifier illustrated in FIG. 8, the input phase circuit 5 changes the phase of the second signal output from the fourth terminal 9d of the 90-degree hybrid circuit 9 in such a way that the phase of the first signal amplified by the first amplifier 3 and the phase of the second signal amplified by the second amplifier 6 are in-phase at the third terminal 7c of the synthesis circuit 7.

More specifically, if the phase of the first signal amplified by the third terminal 7c is θ₁, and, in a case where the input phase circuit 5 is not present, the phase of the second signal amplified by the third terminal 7c is θ₂ and the phase delayed by the input phase circuit 5 is θ₃, the phase θ₃ delayed by the input phase circuit 5 is expressed by, for example, the equation (1) or the equation (2).

Even the balance-type amplifier in which the signal divider circuit 2 includes the 90-degree hybrid circuit 9 can suppress output electrical power and efficiency from decreasing even when the load impedance Z₀ changes similarly to the balance-type amplifier illustrated in FIG. 1.

### Embodiment 4

Embodiment 4 will describe a balance-type amplifier in which the signal divider circuit 2 includes a Wilkinson divider circuit 10.

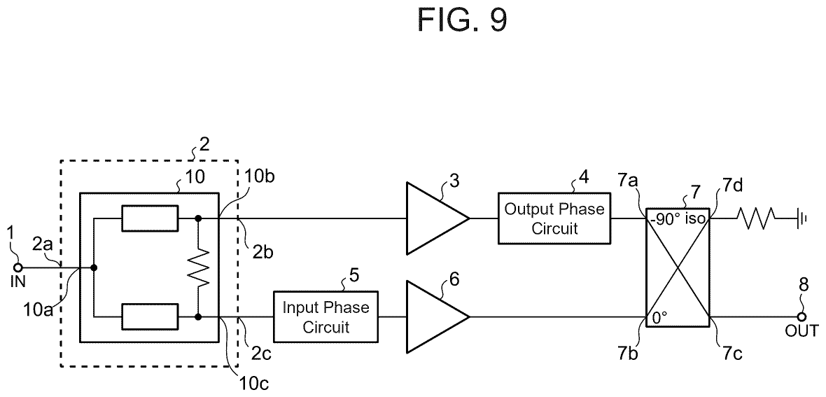

FIG. 9 is a configuration diagram illustrating the balance-type amplifier according to Embodiment 4. Note that, in FIG. 9, the same reference numerals as those in FIG. 1 indicate identical or corresponding parts, and therefore detailed description thereof will be omitted.

The Wilkinson divider circuit 10 includes a first terminal 10a, a second terminal 10b, and a third terminal 10c.

The first terminal 10a is an input terminal to which a high frequency signal that is an amplification target signal is given.

The second terminal 10b is an output terminal that outputs a first signal, and the third terminal 10c is an output terminal that outputs a second signal.

When the high frequency signal is given to the first terminal 10a, the Wilkinson divider circuit 10 divides the high frequency signal into two signals.

The Wilkinson divider circuit 10 outputs the first signal as one of the two divided signals from the second terminal 10b to the first amplifier 3, and outputs the second signal as the other signal of the two divided signals from the third terminal 10c to the input phase circuit 5.

In the balance-type amplifier illustrated in FIG. 9, the Wilkinson divider circuit 10 is applied to the balance-type amplifier illustrated in FIG. 1. However, this is merely an example, and the Wilkinson divider circuit 10 may be applied to the balance-type amplifier illustrated in FIG. 7.

Also in the balance-type amplifier illustrated in FIG. 9, the input phase circuit 5 changes the phase of the second signal output from the third terminal 10c of the Wilkinson divider circuit 10 in such a way that the phase of the first signal amplified by the first amplifier 3 and the phase of the second signal amplified by the second amplifier 6 are in-phase at the third terminal 7c of the synthesis circuit 7.

More specifically, if the phase of the first signal amplified by the third terminal 7c is θ₁, and, in the case where the input phase circuit 5 is not present, the phase of the second signal amplified by the third terminal 7c is θ₂ and the phase delayed by the input phase circuit 5 is θ₃, the phase θ₃ delayed by the input phase circuit 5 is expressed by, for example, the equation (1) or the equation (2).

Even the balance-type amplifier in which the signal divider circuit 2 includes the Wilkinson divider circuit 10 can suppress output electrical power and efficiency from decreasing even when the load impedance Z₀ changes similarly to the balance-type amplifier illustrated in FIG. 1.

### Embodiment 5

Embodiment 5 will describe a balance-type amplifier that includes a third amplifier 11 and a fourth amplifier 12.

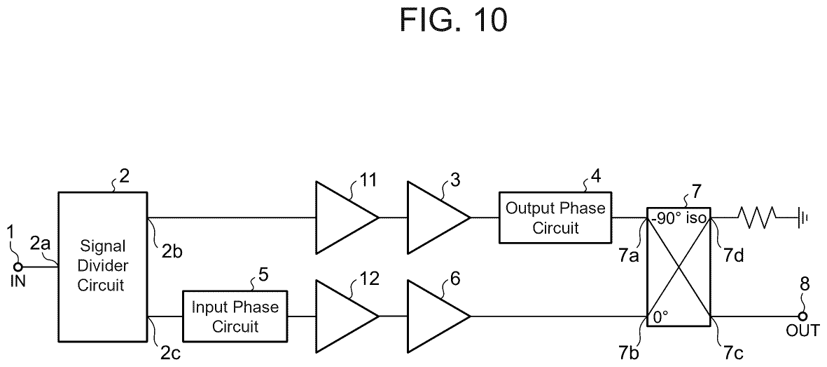

FIG. 10 is a configuration diagram illustrating the balance-type amplifier according to Embodiment 5. Note that, in FIG. 10, the same reference numerals as those in FIG. 1 indicate identical or corresponding parts, and therefore detailed description thereof will be omitted.

The balance-type amplifier illustrated in FIG. 10 includes the signal input terminal 1, the signal divider circuit 2, the third amplifier 11, the first amplifier 3, the output phase circuit 4, the input phase circuit 5, the fourth amplifier 12, the second amplifier 6, the synthesis circuit 7, and the signal output terminal 8.

The third amplifier 11 is implemented as, for example, a semi-discrete amplifier enclosed in a high frequency package or an MMIC type amplifier formed on a semiconductor substrate.

The third amplifier 11 is connected with the first amplifier 3 in series. In the balance-type amplifier illustrated in FIG. 10, the third amplifier 11 is connected with an input side of the first amplifier 3. However, this is merely an example, and the third amplifier 11 may be connected with the output side of the first amplifier 3. In a case where the third amplifier 11 is connected with the output side of the first amplifier 3, an output impedance of the third amplifier 11 is matched with the first impedance.

The third amplifier 11 amplifies the first signal output from the second terminal 2b of the signal divider circuit 2.

The third amplifier 11 outputs the amplified first signal to the first amplifier 3.

The fourth amplifier 12 is implemented as, for example, a semi-discrete amplifier enclosed in a high frequency package or an MMIC type amplifier formed on a semiconductor substrate.

The fourth amplifier 12 is connected with the second amplifier 6 in series. In the balance-type amplifier illustrated in FIG. 10, the fourth amplifier 12 is connected with the input side of the second amplifier 6. However, this is merely an example, and the fourth amplifier 12 may be connected with the output side of the second amplifier 6. In a case where the fourth amplifier 12 is connected with the output side of the second amplifier 6, an output impedance of the fourth amplifier 12 is matched with the second impedance.

The fourth amplifier 12 amplifies the second signal output from the input phase circuit 5.

The fourth amplifier 12 outputs the amplified second signal to the second amplifier 6.

In the balance-type amplifier illustrated in FIG. 10, the third amplifier 11 and the fourth amplifier 12 are applied to the balance-type amplifier illustrated in FIG. 1. However, this is merely an example, and the third amplifier 11 and the fourth amplifier 12 may be applied to the balance-type amplifier illustrated in FIG. 7.

Even in the case where the balance-type amplifier includes the third amplifier 11 connected with the first amplifier 3 in series and the fourth amplifier 12 connected with the second amplifier 6 in series, the balance-type amplifier can suppress output electrical power and efficiency from decreasing even when the load impedance Z₀ changes similarly to the balance-type amplifier illustrated in FIG. 1.

### Embodiment 6

Embodiment 6 will describe a balance-type amplifier that includes a fifth amplifier 13.

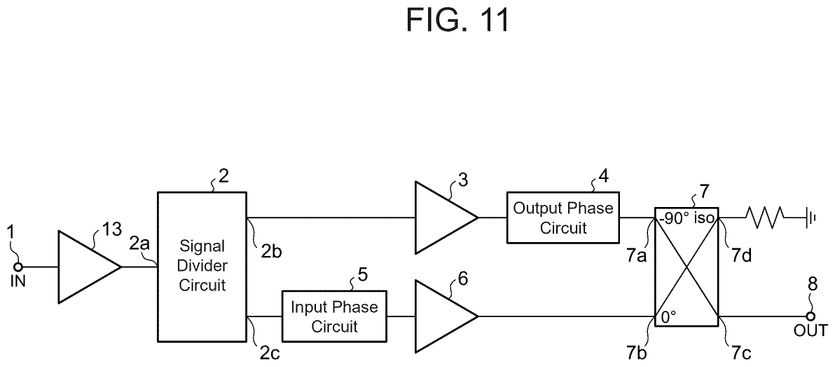

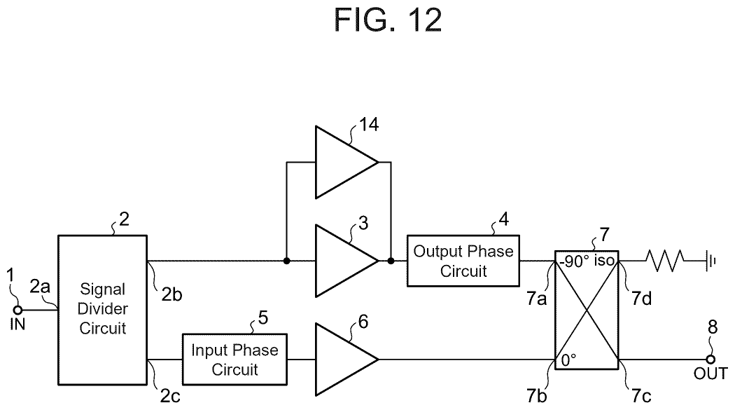

FIG. 11 is a configuration diagram illustrating the balance-type amplifier according to Embodiment 6. Note that, in FIG. 11, the same reference numerals as those in FIG. 1 indicate identical or corresponding parts, and therefore detailed description thereof will be omitted.

The balance-type amplifier illustrated in FIG. 11 includes the signal input terminal 1, the fifth amplifier 13, the signal divider circuit 2, the first amplifier 3, the output phase circuit 4, the input phase circuit 5, the second amplifier 6, the synthesis circuit 7, and the signal output terminal 8.

The fifth amplifier 13 is implemented as, for example, a semi-discrete amplifier enclosed in a high frequency package or an MMIC type amplifier formed on a semiconductor substrate.

The fifth amplifier 13 amplifies a high frequency signal that is an amplification target signal given to the signal input terminal 1.

The fifth amplifier 13 outputs the amplified high frequency signal to the first terminal 2a of the signal divider circuit 2.

In the balance-type amplifier illustrated in FIG. 11, the fifth amplifier 13 is applied to the balance-type amplifier illustrated in FIG. 1. However, this is merely an example, and the fifth amplifier 13 may be applied to the balance-type amplifier illustrated in FIG. 7.

Even in the case where the balance-type amplifier includes the fifth amplifier 13, the balance-type amplifier can suppress output electrical power and efficiency from decreasing even when the load impedance Z₀ changes similarly to the balance-type amplifier illustrated in FIG. 1.

### Embodiment 7

Embodiment 7 will describe a balance-type amplifier that includes a sixth amplifier 14.

FIG. 12 is a configuration diagram illustrating the balance-type amplifier according to Embodiment 7. Note that, in FIG. 12, the same reference numerals as those in FIG. 1 indicate identical or corresponding parts, and therefore detailed description thereof will be omitted.

The balance-type amplifier illustrated in FIG. 12 includes the signal input terminal 1, the signal divider circuit 2, the first amplifier 3, the sixth amplifier 14, the output phase circuit 4, the input phase circuit 5, the second amplifier 6, the synthesis circuit 7, and the signal output terminal 8.

The sixth amplifier 14 is implemented as, for example, a semi-discrete amplifier enclosed in a high frequency package or an MMIC type amplifier formed on a semiconductor substrate.

The sixth amplifier 14 is connected with the first amplifier 3 in parallel.

The sixth amplifier 14 amplifies the first signal output from the second terminal 2b of the signal divider circuit 2.

The sixth amplifier 14 outputs the amplified first signal to the output phase circuit 4.

In a case where the first amplifier 3 and the sixth amplifier 14 are connected in parallel, each of the output impedance of the first amplifier 3 and the output impedance of the sixth amplifier 14 is matched with the first impedance.

In the balance-type amplifier illustrated in FIG. 12, the sixth amplifier 14 is connected with the first amplifier 3 in parallel. However, this is merely an example, and the sixth amplifier 14 may be connected with the second amplifier 6 in parallel. In a case where the second amplifier 6 and the sixth amplifier 14 are connected in parallel, each of the output impedance of the second amplifier 6 and the output impedance of the sixth amplifier 14 is matched with the second impedance.

In the balance-type amplifier illustrated in FIG. 12, the sixth amplifier 14 is applied to the balance-type amplifier illustrated in FIG. 1. However, this is merely an example, and the sixth amplifier 14 may be applied to the balance-type amplifier illustrated in FIG. 7.

Even in the case where the balance-type amplifier includes the sixth amplifier 14, the balance-type amplifier can suppress output electrical power and efficiency from decreasing even when the load impedance Z₀ changes similarly to the balance-type amplifier illustrated in FIG. 1.

In the balance-type amplifiers according to Embodiments 1 to 7, the output impedance of the first amplifier 3 is matched with the first impedance, and the output impedance of the second amplifier 6 is matched with the second impedance. However, this is merely an example, and, the output matching circuit 3c and the output matching circuit 6c may be configured as adjustable matching circuits in such a way that the output impedance of the first amplifier 3 is matched with the first impedance corresponding to the load impedance Z₀ before change, and the output impedance of the second amplifier 6 is matched with the second impedance corresponding to the load impedance Z₀ before change.

If, for example, the load impedance Z₀ before change is 60Ω, the output matching circuit 3c is adjusted in such a way that the output impedance of the first amplifier 3 is higher than 60Ω, and the output matching circuit 6c is adjusted in such a way that the output impedance of the second amplifier 6 is lower than 60Ω. Furthermore, if the load impedance Z₀ before change is 70Ω, the output matching circuit 3c is adjusted in such a way that the output impedance of the first amplifier 3 is higher than 70Ω, and the output matching circuit 6c is adjusted in such a way that the output impedance of the second amplifier 6 is lower than 70Ω.

Note that the present disclosure allows free combinations of the embodiments, modification to any components in the embodiments, or omission of any components in the embodiments.

### INDUSTRIAL APPLICABILITY

The present disclosure is suitable for a balance-type amplifier.

### REFERENCE SIGNS LIST

1: Signal input terminal, 2: Signal divider circuit, 2a: First terminal, 2b: Second terminal, 2c: Third terminal, 3: First amplifier, 3a: Input matching circuit, 3b: First amplification element, 3c: Output matching circuit, 4: Output phase circuit, 5: Input phase circuit, 6: Second amplifier, 6a: Input matching circuit, 6b: Second amplification element, 6c: Output matching circuit, 7: Synthesis circuit, 7a: First terminal, 7b: Second terminal, 7c: Third terminal, 7d: Fourth terminal, 8: Signal output terminal, 9: 90-degree hybrid circuit, 9a: First terminal, 9b: Second terminal, 9c: Third terminal, 9d: Fourth terminal, 10: Wilkinson divider circuit, 10a: First terminal, 10b: Second terminal, 10c: Third terminal, 11: Third amplifier, 12: Fourth amplifier, 13: Fifth amplifier, 14: Sixth amplifier

1. A balance-type amplifier comprising:
a signal divider circuit to divide an amplification target signal into two divided signals including a first signal and a second signal, output the first signal and the second signal;
a first amplifier to amplify the first signal output from the signal divider circuit;
a second amplifier to amplify the second signal output from the signal divider circuit;
a synthesis circuit to perform synthesization of the first signal amplified by the first amplifier and the second signal amplified by the second amplifier;
an output phase circuit having an electrical length of 90 degrees and provided between the first amplifier and the synthesis circuit; and
an input phase circuit provided between the signal divider circuit and the second amplifier, the input phase circuit performing a phase shift of a phase of the second signal output from the signal divider circuit in such a way that a phase of the first signal amplified by the first amplifier and the phase of the second signal amplified by the second amplifier are in-phase at a point of the synthesization in the synthesis circuit of the first signal amplified by the first amplifier and the second signal amplified by the second amplifier, wherein
the first amplifier includes a first matching circuit to match an output impedance of the first amplifier with a first impedance different from an impedance of a load connected with an output side of the synthesis circuit,
the second amplifier includes a second matching circuit to match an output impedance of the second amplifier with a second impedance different from the impedance of the load,
one of the first impedance and the second impedance is higher than the impedance of the load, and another of the first impedance and the second impedance is lower than the impedance of the load,
the synthesis circuit includes a 90-degree hybrid circuit including:
a first terminal to which the first signal amplified by the first amplifier is given, a second terminal to which the second signal amplified by the second amplifier is given; and
a third terminal to output a synthesis signal of the first signal amplified by the first amplifier and the second signal amplified by the second amplifier.

2. A balance-type amplifier comprising:
a signal divider circuit to divide an amplification target signal into two divided signals including a first signal and a second signal, output the first signal and the second signal;
a first amplifier to amplify the first signal output from the signal divider circuit;
a second amplifier to amplify the second signal output from the signal divider circuit;
a synthesis circuit to perform synthesization of the first signal amplified by the first amplifier and the second signal amplified by the second amplifier;
an output phase circuit having an electrical length of 90 degrees provided between the second amplifier and the synthesis circuit; and
an input phase circuit provided between the signal divider circuit and the first amplifier, the input phase circuit performing a phase shift of the phase of the first signal output from the signal divider circuit in such a way that the phase of the first signal amplified by the first amplifier and a phase of the amplified by the second amplifier are in-phase at a point of the synthesization in the synthesis circuit of the first signal amplified by the first amplifier and the second signal amplified by the second amplifier, wherein
the first amplifier includes a first matching circuit to match an output impedance of the first amplifier with a first impedance different from an impedance of a load connected with an output side of the synthesis circuit,
the second amplifier includes a second matching circuit to match an output impedance of the second amplifier with a second impedance different from the impedance of the load, and
one impedance of the first impedance and the second impedance is higher than the impedance of the load, and another impedance of the first impedance and the second impedance is lower than the impedance of the load, wherein
the synthesis circuit includes a 90-degree hybrid circuit including:
a first terminal to which the first signal amplified by the first amplifier is given,
a second terminal to which the second signal amplified by the second amplifier is given; and
a third terminal to output a synthesis signal of the first signal amplified by the first amplifier and the second signal amplified by the second amplifier.

3. The balance-type amplifier according to claim 1, wherein
the first amplifier includes
a first amplification element to amplify the first signal output from the signal divider circuit, and
an output matching circuit to match an output impedance of the first amplification element with the first impedance, the output matching circuit being the first matching circuit, and having one end connected with an output side of the first amplification element and another end connected with an input side of the output phase circuit, and
the second amplifier includes
a second amplification element to amplify the second signal subjected to the phase shift performed by the input phase circuit, and
an output matching circuit to match an output impedance of the second amplification element with the second impedance, the output matching circuit being the second matching circuit, and having one end connected with an output side of the second amplification element and another end connected with an input side of the synthesis circuit.

4. The balance-type amplifier according to claim 2, wherein
the first amplifier includes
a first amplification element to amplify the first signal subjected to the phase shift performed by the input phase circuit, and
an output matching circuit to match an output impedance of the first amplification element with the first impedance, the output matching circuit being the first matching circuit, and having one end connected with an output side of the first amplification element and another end connected with an input side of the synthesis circuit, and
the second amplifier includes
a second amplification element to amplify the second signal output from the signal divider circuit, and
an output matching circuit to match an output impedance of the second amplification element with the second impedance, the output matching circuit being the second matching circuit, and having one end connected with an output side of the second amplification element and another end connected with an input side of the output phase circuit.

5. The balance-type amplifier according to claim 1, wherein
the signal divider circuit includes a 90-degree hybrid circuit including:
a first terminal to which the amplification target signal is given;
a second terminal to output the first signal that is one of the two divided signals; and
a third terminal to output the second signal that is one of the two divided signals.

6. The balance-type amplifier according to claim 1, wherein
the signal divider circuit includes a Wilkinson divider circuit including:
a first terminal to which the amplification target signal is given;
a second terminal to output the first signal that is one of the two divided signals; and
a third terminal to output the second signal that is one of the two divided signals.

7. The balance-type amplifier according to claim 1, further comprising:
a third amplifier connected with the first amplifier in series; and
a fourth amplifier connected with the second amplifier in series.

8. The balance-type amplifier according to claim 1, further comprising a fifth amplifier to amplify the amplification target signal and output the amplified amplification target signal to the signal divider circuit.

9. The balance-type amplifier according to claim 1, further comprising a sixth amplifier connected in parallel with one of the first amplifier and the second amplifier.

10. The balance-type amplifier according to claim 2, wherein
the signal divider circuit includes a 90-degree hybrid circuit including:
a first terminal to which the amplification target signal is given;
a second terminal to output the first signal that is one of the two divided signals; and
a third terminal to output the second signal that is one of the two divided signals.

11. The balance-type amplifier according to claim 2, wherein
the signal divider circuit includes a Wilkinson divider circuit including:
a first terminal to which the amplification target signal is given;
a second terminal to output the first signal that is one of the two divided signals; and
a third terminal to output the second signal that is one of the two divided signals.

12. The balance-type amplifier according to claim 2, further comprising:
a third amplifier connected with the first amplifier in series; and
a fourth amplifier connected with the second amplifier in series.

13. The balance-type amplifier according to claim 2, further comprising a fifth amplifier to amplify the amplification target signal and output the amplified amplification target signal to the signal divider circuit.

14. The balance-type amplifier according to claim 2, further comprising a sixth amplifier connected in parallel with one of the first amplifier and the second amplifier.
